(19) United States
(12) Patent Application Publication
(10) Pub. No.: US 2026/0057666 A1
(43) Pub. Date: Feb. 26, 2026

(54) BOUNDARY VERIFICATION SYSTEMS

(71) Applicant: Indigo Ag, Inc., Charlestown, MA (US)

(72) Inventors: Ben SLONE, Boston, MA (US); Kristen MOREAU, Manchester Center, VT (US); Sarah GODOSHIAN, Laguna Beach, CA (US); Rebecca HERRON, Denver, CO (US); Matthew HILBERT, Redding, CT (US); Ashley KASPER, Des Moines, IA (US)

(21) Appl. No.: 19/104,177

(22) PCT Filed: Aug. 15, 2023
(86) PCT No.: PCT/US2023/030295

§ 371 Date: Feb. 14, 2025

Related U.S. Application Data
(60) Provisional application No. 63/371,510, filed on Aug. 15, 2022.

(51) Int. Cl. G06V 20/13; G06F 30/27; G06V 10/74; G06V 10/764; G06V 10/82; G06V 10/94; G06V 20/10

(52) U.S. Cl. CPC G06V 20/13; G06F 30/27; G06V 10/761; G06V 10/764; G06V 10/82; G06V 10/945; G06V 20/188

(57) ABSTRACT

Boundary Verification Systems are provided. A proposed boundary of a geographic area is read. One or more boundary validation criteria is read. One or more attribute of the geographic area over time is determined from satellite imagery of the geographic area. The proposed boundary is validated against the one or more boundary validation criteria and the one or more attribute. A revised boundary is generated based on the proposed boundary and the one or more attribute.

### RELATED APPLICATION(S)

This application claims the benefit of priority to U.S. Provisional Application No. 63/371,510, filed Aug. 15, 2022, which is incorporated herein by reference in its entirety.

### BACKGROUND

Embodiments of the present disclosure relate to geographic information, and more specifically, to boundary verification and correction such as applied to agricultural field boundaries.

### SUMMARY

According to certain aspects of the present disclosure, systems and methods are disclosed for verifying boundary information in agricultural applications.

In an embodiment, a method comprises reading a proposed boundary of a geographic area, reading one or more boundary validation criteria, determining from satellite imagery of the geographic area one or more attribute of the geographic area over time, validating the proposed boundary against the one or more boundary validation criteria and the one or more attribute, generating a revised boundary based on the proposed boundary and the one or more attribute.

In some embodiments, the geographic area is an agricultural field.

In some embodiments, the one or more boundary validation criteria is based on a program eligibility.

In some embodiments, the one or more attribute is a crop type or presence of wetlands.

In some embodiments, generating the revised boundary comprises removing from the proposed boundary regions not conforming to the one or more boundary validation criteria. In some embodiments, the method further comprises receiving the proposed boundary from a user via drawing on a map presented within a GUI of a user device. In some embodiments, the method further comprises receiving from a user a list of field boundaries, wherein the proposed boundary is selected from the list. In some embodiments, the method further comprises presenting the proposed boundary and the revised boundary to a user on a map presented within a GUI of a user device. In some embodiments, the method further comprises receiving from the user an indication of acceptance or rejection of the revised boundary. In some embodiments, the one or more attribute is a crop type and wherein determining the one or more attribute of the geographic area over time comprises providing the satellite imagery to a machine learning model and receiving therefrom the one or more attribute over time. In some embodiments, the machine learning model is configured to provide an in-season estimate of one or more crop type. In some embodiments, the machine learning model comprises a plurality of forecast models, each forecast model configured to forecast a vegetative index; and a classification model configured to receive the forecasted vegetative indices and determine therefrom the crop type. In some embodiments, each of the plurality of forecast models comprises an artificial neural network. In some embodiments, the artificial neural networks comprise a convolutional or recurrent neural network. In some embodiments, the classification model comprises a gradient boosting model. In some embodiments, the one or more attribute is presence of surface water and wherein determining the one or more attribute of the geographic area over time comprises applying a threshold to one or more vegetative index of the satellite imagery.

In some embodiments, a system comprises a computing node comprising a computer readable storage medium having program instructions embodied therewith, the program instructions executable by a processor of the computing node to cause the processor to perform a method according to any one of the above embodiments.

In some embodiments, a computer program product for boundary verification and rectification, comprises a computer readable storage medium having program instructions embodied therewith, the program instructions executable by a processor to cause the processor to perform a method according to any one of the above embodiments.

### BRIEF DESCRIPTION OF THE DRAWINGS

The accompanying drawings, which are incorporated into and constitute a part of this specification, illustrate various exemplary embodiments and together with the description, serve to explain the principles of the disclosed embodiments.

FIG. 1 is an exemplary model workflow for verifying boundary information, according to one or more aspects of the present disclosure.

FIG. 2 is an exemplary flowchart of an API method for verifying boundary information, according to one or more aspects of the present disclosure.

FIG. 3 is a graph illustrating the estimation of a 2022 crop species, according to one or more aspects of the present disclosure.

FIG. 4 is an illustration of the same estimation of a 2022 crop species at a later in-season date, according to one or more aspects of the present disclosure.

FIG. 5 is an exemplary prediction result, according to one or more aspects of the present disclosure.

FIG. 6 is an exemplary prediction result, according to one or more aspects of the present disclosure.

FIG. 7 is an exemplary prediction result, according to one or more aspects of the present disclosure.

FIG. 8 is an exemplary prediction result, according to one or more aspects of the present disclosure.

FIG. 9 is an exemplary prediction result, according to one or more aspects of the present disclosure.

FIG. 10 is an exemplary process for a pre-check API workflow, according to one or more aspects of the present disclosure.

FIG. 11 is an exemplary display of a customer leveraging the API, according to one or more aspects of the present disclosure.

FIG. 12 is an exemplary display of a customer leveraging the API once an action is selected, according to one or more aspects of the present disclosure.

FIG. 13 displays an accepted boundary screen, where the user or grower completes fixing the boundary, according to one or more aspects of the present disclosure.

FIG. 14 illustrates a method of boundary verification according to embodiments of the present disclosure.

FIG. 15 is an exemplary computing node.

### DETAILED DESCRIPTION

Many use cases require checks to verify field eligibility for programs (e.g., Carbon protocols). However, eligibility checks may occur very late in the grower journey, after a grower has already invested time into a program. In an illustrative program, 18% of participating fields and 54% of growers encountered an eligibility flag late in the experience. To address this pain point, the present disclosure provides automated and semi-automated systems for boundary verification based on machine learning methods, and automatic revision of boundaries to ensure compliance with given program guidelines.

After implementation of the present disclosure in the illustrative program, 9.7% of fields were ineligible late in the journey, for a 46% reduction in participating fields with eligibility issues. As observed, more growers were able to edit and resolve their errors earlier in the process. In addition, the boundary “pre-check” process allows clients to upload a list of fields and receive initial feedback on whether the fields are eligible. In addition to field eligibility, there are other conditions a grower will need to meet to be eligible for certain programs, such as adopting a new sustainable practice change.

Accordingly, in various embodiments, the ability to pre-check field eligibility and modify fields before are provided. In various embodiments, an API is provided that returns results and metadata for multiple eligibility checks on field boundaries.

### Definitions

As used herein, the term “exemplary” is used in the sense of “example,” rather than “ideal.” Moreover, the terms “a” and “an” herein do not denote a limitation of quantity, but rather denote the presence of one or more of the referenced items.

As used herein an “ecosystem benefit” is used equivalently with “ecosystem attribute” or “environmental attribute,” each refer to an environmental characteristic (for example, as a result of agricultural production) that may be quantified and valued (for example, as an ecosystem credit or sustainability claim). Examples of ecosystem benefits include without limitation reduced water use, reduced nitrogen use, increased soil carbon sequestration, greenhouse gas emission avoidance, etc. An example of a mandatory program requiring accounting of ecosystem attributes is California's Low Carbon Fuel Standard (LCFS). Field-based agricultural management practices can be a means for reducing the carbon intensity of biofuels (e.g., biodiesel from soybeans).

An “ecosystem impact” is a change in an ecosystem attribute relative to a baseline. In various embodiments, baselines may reflect a set of regional standard practices or production (a comparative baseline), prior production practices and outcomes for a field or farming operation (a temporal baseline), or a counterfactual alternative scenario (a counterfactual baseline). For example, a temporal baseline for determination of an ecosystem impact may be the difference between a safrinha crop production period and the safrinha crop production period of the prior year. In some embodiments, an ecosystem impact can be generated from the difference between an ecosystem attribute for the latest crop production period and a baseline ecosystem attribute averaged over a number (e.g., 2, 3, 4, 5, 6, 7, 8, 9, 10) of prior production periods.

A counterfactual scenario refers to what could have happened within the crop growing season in an area of land given alternative practices. In various embodiments, a counterfactual scenario is based on an approximation of supply shed practices.

An “ecosystem credit” is a unit of value corresponding to an ecosystem benefit or ecosystem impact, where the ecosystem attribute or ecosystem impact is measured, verified, and or registered according to a methodology. In some embodiments, an ecosystem credit may be a report of the inventory of ecosystem attributes (for example, an inventory of ecosystem attributes of a management zone, an inventory of ecosystem attributes of a farming operation, an inventory of ecosystem attributes of a supply shed, an inventory of ecosystem attributes of a supply chain, an inventory of a processed agricultural product, etc.). In some embodiments, an ecosystem credit is a life-cycle assessment. In some embodiments, an ecosystem credit may be a registry issued credit. Optionally, an ecosystem credit is generated according to a methodology approved by an issuer. An ecosystem credit may represent a reduction or offset of an ecologically significant compound (e.g., carbon credits, water credits, nitrogen credits). In some embodiments, a reduction or offset is compared to a baseline of ‘business as usual’ if the ecosystem crediting or sustainability program did not exist (e.g., if one or more practice change made because of the program had not been made).

In some embodiments, a reduction or offset is compared to a baseline of one or more ecosystem attributes (e.g., ecosystem attributes of one or more: field, sub-field region, county, state, region of similar environment, supply shed geographic region, a supply shed, etc.) during one or more prior production period. For example, ecosystem attributes of a field in 2022 may be compared to a baseline of ecosystem attributes of the field in 2021. In some embodiments, a reduction or offset is compared to a baseline of one or more ecosystem attributes (e.g., ecosystem attributes of one or more: field, sub-field region, county, state, region of similar environment, supply shed geographic region, a supply shed, etc.) during the same production period. For example, ecosystem attributes of a field may be compared to a baseline of ecosystem attributes of a supply shed comprising the field. An ecosystem credit may represent a permit to reverse an ecosystem benefit, for example, a license to emit one metric ton of carbon dioxide. A carbon credit represents a measure (e.g., one metric ton) of carbon dioxide or other greenhouse gas emissions reduced, avoided or removed from the atmosphere. A nutrient credit, for example a water quality credit, represents pounds of a chemical removed from an environment (e.g., by installing or restoring nutrient-removal wetlands) or reduced emissions (e.g., by reducing rates of application of chemical fertilizers, managing the timing or method of chemical fertilizer application, changing type of fertilizer, etc.). Examples of nutrient credits include nitrogen credits and phosphorous credits. A water credit represents a volume (e.g., 1000 gallons) of water usage that is reduced or avoided, for example by reducing irrigation rates, managing the timing or method of irrigation, employing water conservation measures such as reducing evaporation application.

A “sustainability claim” is a set of one or more ecosystem benefits associated with an agricultural product (for example, including ecosystem benefits associated with production of an agricultural product). Sustainability claims may or may not be associated with ecosystem credits. For example, a consumer package good entity may contract raw agricultural products from producers reducing irrigation, in order to make a sustainability claim of supporting the reduction of water demand on the final processed agricultural product. The producers reducing irrigation may or may not also participate in a water ecosystem credit program, where ecosystem credits are generated based on the quantity of water that is actually reduced compared against a baseline.

“Offsets” are credits generated by third-parties outside the value chain of the party with the underlying carbon liability (e.g., oil company that generates greenhouse gases from combusting hydrocarbons purchases carbon credit from a farmer).

“Insets” are ecosystem resource (e.g., carbon dioxide) reductions within the value chain of the party with the underlying carbon liability (e.g., oil company who makes biodiesel reduces carbon intensity of biodiesel by encouraging farmers to produce the underlying soybean feedstock using sustainable farming practices). Insets are considered Scope 1 reductions.

Emissions of greenhouse gases are often categorized as Scope 1, Scope 2, or Scope 3. Scope 1 emissions are direct greenhouse gas emissions that occur from sources that are controlled or owned by an organization. Scope 2 emissions are indirect greenhouse gas emissions associated with purchase of electricity, stem, heating, or cooling. Scope 3 emissions are the result of activities from assets not owned or controlled by the reporting organization, but that the organization indirectly impacts in its value chain. Scope 3 emissions represent all emissions associated with an organization's value chain that are not included in that organization's Scope 1 or Scope 2 emissions. Scope 3 emissions include activities upstream of the reporting organization or downstream of the reporting organization. Upstream activities include, for example, purchased goods and services (e.g., agricultural production such as wheat, soybeans, or corn may be purchased inputs for production of animal feed), upstream capital goods, upstream fuel and energy, upstream transportation and distribution (e.g., transportation of raw agricultural products such as grain from the field to a grain elevator), waste generated in upstream operations, business travel, employee commuting, or leased assets. Downstream activities include, for example, transportation and distribution other than with the vehicles of the reporting organization, processing of sold goods, use of goods sold, end of life treatment of goods sold, leased assets, franchises, or investments.

An ecosystem credit may generally be categorized as either an inset (when associated with the value chain of production of a particular agricultural product), or an offset, but not both concurrently.

As used herein, a “crop-growing season” may refer to fundamental unit of grouping crop events by non-overlapping periods of time. In various embodiments, harvest events are used where possible.

An “issuer” is an issuer of ecosystem credits, which may be a regulatory authority or another trusted provider of ecosystem credits. An issuer may alternatively be referred to as a “registry”.

A “token” (alternatively, an “ecosystem credit token”) is a digital representation of an ecosystem benefit, ecosystem impact, or ecosystem credit. The token may include a unique identifier representing one or more ecosystem credits, ecosystem attribute, or ecosystem impact, or, in some embodiments a putative ecosystem credit, putative ecosystem attribute, or putative ecosystem impact, associated with a particular product, production location (e.g., a field), production period (e.g., crop production season), and/or production zone cycle (e.g., a single management zone defined by events that occur over the duration of a single crop production season).

“Ecosystem credit metadata” is at least information sufficient to identify an ecosystem credit issued by an issuer of ecosystem credits. For example, the metadata may include one or more of a unique identifier of the credit, an issuer identifier, a date of issuance, identification of the algorithm used to issue the credit, or information regarding the processes or products giving rise to the credit. In some embodiments, the credit metadata may include a product identifier as defined herein. In other embodiments, the credit is not tied to a product at generation, and so there is no product identifier included in the credit metadata.

A “product” is any item of agricultural production, including crops and other agricultural products, in their raw, as-produced state (e.g., wheat grains), or as processed (e.g., oils, flours, polymers, consumer goods (e.g., crackers, cakes, plant based meats, animal-based meats (for example, beef from cattle fed a product such as corn grown from a particular field), bioplastic containers, etc.). In addition to harvested physical products, a product may also include a benefit or service provided via use of the associated land (for example, for recreational purposes such as a golf course), pasture land for grazing wild or domesticated animals (where domesticated animals may be raised for food or recreation).

“Product metadata” are any information regarding an underlying product, its production, and/or its transaction which may be verified by a third party and may form the basis for issuance of an ecosystem credit and/or sustainability claim. Product metadata may include at least a product identifier, as well as a record of entities involved in transactions.

As used herein, “quality” or a “quality metric” may refer to any aspect of an agricultural product that adds value. In some embodiments, quality is a physical or chemical attribute of the crop product. For example, a quality may include, for a crop product type, one or more of: a variety; a genetic trait or lack thereof; genetic modification of lack thereof; genomic edit or lack thereof; epigenetic signature or lack thereof; moisture content; protein content; carbohydrate content; ash content; fiber content; fiber quality; fat content; oil content; color; whiteness; weight; transparency; hardness; percent chalky grains; proportion of corneous endosperm; presence of foreign matter; number or percentage of broken kernels; number or percentage of kernels with stress cracks; falling number; farinograph; adsorption of water; milling degree; immature grains; kernel size distribution; average grain length; average grain breadth; kernel volume; density; L/B ratio; wet gluten; sodium dodecyl sulfate sedimentation; toxin levels (for example, mycotoxin levels, including vomitoxin, fumonisin, ochratoxin, or aflatoxin levels); and damage levels (for example, mold, insect, heat, cold, frost, or other material damage).

In some embodiments, quality is an attribute of a production method or environment. For example, quality may include, for a crop product, one or more of: soil type; soil chemistry; climate; weather; magnitude or frequency of weather events; soil or air temperature; soil or air moisture; degree days; rain fed; irrigated or not; type of irrigation; tillage frequency; tillage type; cover crop (present or historical); fallow seasons (present or historical); crop rotation; organic; shade grown; greenhouse; level and types of fertilizer use; levels and type of chemical use; levels and types of herbicide use; pesticide-free; levels and types of pesticide use; no-till; use of organic manure and byproducts; minority produced; fair-wage; geography of production (e.g., country of origin, American Viticultural Area, mountain grown); pollution-free production; reduced pollution production; levels and types of greenhouse gas production; carbon neutral production; levels and duration of soil carbon sequestration; and others. In some embodiments, quality is affected by, or may be inferred from, the timing of one or more production practices. For example, food grade quality for crop products may be inferred from the variety of plant, damage levels, and one or more production practices used to grow the crop. In another example, one or more qualities may be inferred from the maturity or growth stage of an agricultural product such as a plant or animal. In some embodiments, a crop product is an agricultural product.

In some embodiments, quality is an attribute of a method of storing an agricultural good (e.g., the type of storage: bin, bag, pile, in-field, box, tank, or other containerization), the environmental conditions (e.g., temperature, light, moisture, relative humidity, presence of pests, CO2 levels) during storage of the crop product, method of preserving the crop product (e.g., freezing, drying, chemically treating), or a function of the length of time of storage. In some embodiments, quality may be calculated, derived, inferred, or subjectively classified based on one or more measured or observed physical or chemical attributes of a crop product, its production, or its storage method. In some embodiments, a quality metric is a grading or certification by an organization or agency. For example, grading by the USDA, organic certification, or non-GMO certification may be associated with a crop product. In some embodiments, a quality metric is inferred from one or more measurements made of plants during growing season. For example, wheat grain protein content may be inferred from measurement of crop canopies using hyperspectral sensors and/or NIR or visible spectroscopy of whole wheat grains. In some embodiments, one or more quality metrics are collected, measured, or observed during harvest. For example, dry matter content of corn may be measured using near-infrared spectroscopy on a combine. In some embodiments, the observed or measured value of a quality metric is compared to a reference value for the metric. In some embodiments, a reference value for a metric (for example, a quality metric or a quantity metric) is an industry standard or grade value for a quality metric of a particular agricultural good (for example, U.S. No. 3 Yellow Corn, Flint), optionally as measured in a particular tissue (for example, grain) and optionally at a particular stage of development (for example, silking). In some embodiments, a reference value is determined based on a supplier's historical production record or the historical production record of present and/or prior marketplace participants.

A “field” is the area where agricultural production practices are being used (for example, to produce a transacted agricultural product) and/or ecosystem credits and/or sustainability claims.

As used herein, a “field boundary” may refer to a geospatial boundary of an individual field. For example, a polygon representing a field's perimeter is a field boundary.

As used herein, an “enrolled field boundary” may refer to the geospatial boundary of an individual field enrolled in at least one ecosystem credit or sustainability claim program on a specific date.

In various embodiments, a field is a unique object that has temporal and spatial dimensions. In various embodiments, the field is enrolled in one or more programs, where each program corresponds to a methodology. As used herein a “methodology” (equivalently “program eligibility requirements” or “program requirements”) is a set of requirements associated with a program, and may include, for example, eligibility requirements for the program (for example, eligible regions, permitted practices, eligible participants (for example, size of farms, types of product permitted, types of production facilities permitted, etc.) and or environmental effects of activities of program participants, reporting or oversight requirements, required characteristics of technologies (including modeling technologies, statistical methods, etc.) permitted to be used for prediction, quantification, verification of results by program participants, etc. Examples of methodologies include protocols administered by Climate Action Reserve (CAR) (climateactionreserve.org), such as the Soil Enrichment Protocol; methodologies administered by Verra (verra.org), such as the Methodology for Improved Agricultural Land Management, farming sustainability certifications, life cycle assessment, and other similar programs. In various embodiments, the field data object includes field metadata. “One or more methodologies” refers to a data structure comprising program eligibility requirements for a plurality of programs. More briefly, a methodology may be a set of rules set by a registry or other third party, while a program implements the rules set in the methodology.

In various embodiments, the field metadata includes a field identifier that identifies a farm (e.g., a business) and a farmer who manages the farm (e.g., a user). In various embodiments, the field metadata includes field boundaries that are a collection of one or more polygons describing geospatial boundaries of the field. In some embodiments, polygons representing fields or regions within fields (e.g., management event boundaries, etc.) may be detected from remote sensing data using computer vision methods (for example, edge detection, image segmentation, and combinations thereof) or machine learning algorithms (for example, maximum likelihood classification, random tree classification, support vector machine classification, ensemble learning algorithms, convolutional neural network, etc.).

In various embodiments, the field metadata includes farming practices that are a set of farming practices on the field. In various embodiments, farming practices are a collection of practices across multiple years. For example, farming practices include crop types, tillage method, fertilizers and other inputs, etc. as well as temporal information related to each practice which is used to establish crop growing seasons and ultimately to attribute outcomes to practices. In various embodiments, the field metadata includes outcomes. In various embodiments, the outcomes include at least an effect size of the farming practices and an uncertainty of the outcome. In various embodiments, an outcome is a recorded result of a practice, notably: harvest yields, sequestration of greenhouse gases, and/or reduction of emissions of one or more greenhouse gases.

In various embodiments, the field metadata includes agronomic information, such as soil type, climate type, etc. In various embodiments, the field metadata includes evidence of practices and outcomes provided by the grower or other sources. For example, a scale ticket from a grain elevator, an invoice for cover crop seed from a distributor, farm machine data, remote sensing data, a time stamped image or recording, etc. In various embodiments, the field metadata includes product tracing information such as storage locations, intermediaries, final buyer, and tracking identifiers.

In various embodiments, the field object is populated by data entry from the growers directly. In various embodiments, the field object is populated using data from remote sensing (satellite, sensors, drones, etc.). In various embodiments, the field object is populated using data from agronomic data platforms such as John Deere and Granular, and/or data supplied by agronomists, and/or data generated by remote sensors (such as aerial imagery, satellite derived data, farm machine data, soil sensors, etc.). In various embodiments, at least some of the field metadata within the field object is hypothetical for simulating and estimating the potential effect of applying one or more practices (or changing one or more practices) to help growers make decisions as to which practices to implement for optimal economic benefit.

In various embodiments, the system may access one or more model capable of processing the field object, processing the field object (e.g., process the field object based on one or more model), and returning an output based on the metadata contained within the field object. In various embodiments, a collection of models that can be applied to a field object to estimate, simulate, and/or quantify the outcome (e.g., the effect on the environment) of the practices implemented on a given field. In various embodiments, the models may include process-based biogeochemical models. In various embodiments, the models may include machine learning models. In various embodiments, the models may include rule-based models. In various embodiments, the models may include a combination of models (e.g., ensemble models).

As used herein, a “management event” may refer to a grouping of data about one or more farming practices (such as tillage, harvest, etc.) that occur within a field boundary or an enrolled field boundary. A “management event” contains information about the time when the event occurred, and has a geospatial boundary defining where within the field boundary the agronomic data about the event applies. Management events are used for modeling and credit quantification, designed to facilitate grower data entry and assessment of data requirements. Each management event may have a defined management event boundary that can be all or part of the field area defined by the field boundary. A “management event boundary” (equivalently a “farming practice boundary”) is the geospatial boundary of an area over which farming practice action is taken or avoided. In some embodiments, if a farming practice action is an action taken or avoided at a single point, the management event boundary is point location. As used herein, a farming practice and agronomic practice are of equivalent meaning.

As used herein, a “management zone” may refer to an area within an individual field boundary defined by the combination of management event boundaries that describe the presence or absence of management events at any particular time or time window, as well as attributes of the management events (if any event occurred). A management zone may be a contiguous region or a non-contiguous region. A “management zone boundary” may refer to a geospatial boundary of a management zone. In some embodiments, a management zone is an area coextensive with a spatially and temporally unique set of one or more farming practices. In some embodiments, an initial management zone includes historic management events from one or more prior cultivation cycles (for example, at least 2, at least 3, at least 4, at least 5, or a number of prior cultivation cycles required by a methodology). In some embodiments, a management zone generated for the year following the year for which an initial management zone was created will be a combination of the initial management zone and one or more management event boundaries of the next year. A management zone can be a data-rich geospatial object created for each field using an algorithm that crawls through management events (e.g., all management events) and groups the management events into discrete zonal areas based on features associated with the management event(s) and/or features associated with the portion of the field in which the management event(s) occur. The creation of management zones enables the prorating of credit quantification for the area within the field boundary based on the geospatial boundaries of management events.

In some embodiments, a management zone is created by sequentially intersecting a geospatial boundary defining a region wherein management zones are being determined (for example, a field boundary), with each geospatially management event boundary occurring within that region at any particular time or time window, wherein each of the sequential intersection operations creates two branches-one with the intersection of the geometries and one with the difference. The new branches are then processed with the next management event boundary in the sequence, bifurcating whenever there is an area of intersection and an area of difference. This process is repeated for all management event boundaries that occurred in the geospatial boundary defining the region. The final set of leaf nodes in this branching process define the geospatial extent of the set of management zones within the region, wherein each management zone is non-overlapping and each individual management zone contains a unique set of management events relative to any other management zone defined by this process.

As used herein, a “zone-cycle” may refer to a single cultivation cycle on a single management zone within a single field, considered collectively as a pair that define a foundational unit (e.g., also referred to as an “atomic unit”) of quantification for a given field in a given reporting period.

As used herein, a “baseline simulation” may refer to a point-level simulation of constructed baselines for the duration of the reported project period, using initial soil sampling at that point (following SEP requirements for soil sampling and model initialization) and management zone-level grower data (that meets SEP data requirements).

As used herein, a “with-project simulation” may refer to a point-level simulation of adopted practice changes at the management zone level that meet SEP requirements for credit quantification.

As used herein, a “field-level project start date” may refer to the start of the earliest cultivation cycle, where a practice change was detected and attested by a grower.

As used herein, a “required historic baseline period” may refer to years (in 365 day periods, not calendar years) of required historic information prior to the field-level project start date that must fit requirements of the data hierarchy in order to be modeled for credits. A number of required years is specified by the SEP, based on crop rotation and management.

As used herein, a “cultivation cycle” (equivalently a “crop production period” or “production period”) may refer to the period between the first day after harvest or cutting of a prior crop on a field or the first day after the last grazing on a field, and the last day of harvest or cutting of the subsequent crop on a field or the last day of last grazing on a field. For example, a cultivation cycle may be: a period starting with the planting date of current crop and ending with the harvest of the current crop, a period starting with the date of last field prep event in the previous year and ending with the harvest of the current crop, a period starting with the last day of crop growth in the previous year and ending with the harvest or mowing of the current crop, a period starting the first day after the harvest in the prior year and the last day of harvest of the current crop, etc. In some embodiments, cultivation cycles are approximately 365 day periods from the field-level project start date that contain completed crop growing seasons (planting to harvest/mowing, or growth start to growth stop). In some embodiments, cultivation cycles extend beyond a single 365 day period and cultivation cycles are divided into one or more cultivation cycles of approximately 365 days, optionally where each division of time includes one planting event and one harvest or mowing event.

As used herein, a “historic cultivation cycles” may refer to defined in the same way as cultivation cycles, but for the period of time in the required historic baseline period.

As used herein, a “historic segments” may refer to individual historic cultivation cycles, separated from each other in order to use to construct baseline simulations.

As used herein, a “historic crop practices” may refer to crop events occurring within historic cultivation cycles.

As used herein, a “baseline thread/parallel baseline threads” may refer to each baseline thread is a repeating cycle of the required historic baseline period, that begin at the management zone level project start date. The number of baseline threads equals the number of unique historic segments (e.g., one baseline thread per each year of the required historic baseline period). Each baseline thread begins with a unique historic segment and runs in parallel to all other baseline threads to generate baseline simulations for a with-project cultivation cycle.

As used herein, an “overlap in practices” may refer to an unrealistic agronomic combinations that arise at the start of baseline threads, when dates of agronomic events in the concluding cultivation cycle overlap with dates of agronomic events in the historic segment that is starting the baseline thread. In this case, logic is in place based on planting dates and harvest dates to make adjustments based on the type of overlap that is occurring.

An “indication of a geographic region” is a latitude and longitude, an address or parcel id, a geopolitical region (for example, a city, county, state), a region of similar environment (e.g., a similar soil type or similar weather), a supply shed, a boundary file, a shape drawn on a map presented within a GUI of a user device, image of a region, an image of a region displayed on a map presented within a GUI of a user device, a user id where the user id is associated with one or more production locations (for example, one or more fields).

For example, polygons representing fields may be detected from remote sensing data using computer vision methods (for example, edge detection, image segmentation, and combinations thereof) or machine learning algorithms (for example, maximum likelihood classification, random tree classification, support vector machine classification, ensemble learning algorithms, convolutional neural network, etc.).

“Ecosystem observation data” are observed or measured data describing an ecosystem, for example weather data, soil data, remote sensing data, emissions data (for example, emissions data measured by an eddy covariance flux tower), populations of organisms, plant tissue data, and genetic data. In some embodiments, ecosystem observation data are used to connect agricultural activities with ecosystem variables. Ecosystem observation data may include survey data, such as soil survey data (e.g., SSURGO). In various embodiments, the system performs scenario exploration and model forecasting, using the modeling described herein. In various embodiments, the system proposes climate-smart crop fuel feedstock CI integration with an existing model, such as the Greenhouse gases, Regulated Emissions, and Energy use in Technologies Model (GREET), which can be found online at https://greet.es.anl.gov/ (the GREET models are incorporated by reference herein).

A “crop type data layer” is a data layer containing a prediction of crop type, for example USDA Cropland Data Layer provides annual predictions of crop type, and a 30 m resolution land cover map is available from MapBiomas (https://mapbiomas.org/en). A crop mask may also be built from satellite-based crop type determination methods, ground observations including survey data or data collected by farm equipment, or combinations of two or more of: an agency or commercially reported crop data layer (e.g., CDL), ground observations, and satellite-based crop type determination methods.

A “vegetative index” (“VI”) is a value related to vegetation as computed from one or more spectral bands or channels of remote sensing data. Examples include simple ratio vegetation index (“RVI”), perpendicular vegetation index (“PVI”), soil adjusted vegetation index (“SAVI”), atmospherically resistant vegetation index (“ARVI”), soil adjusted atmospherically resistant VI (“SARVI”), difference vegetation index (“DVI”), normalized difference vegetation index (“NDVI”). NDVI is a measure of vegetation greenness which is particularly sensitive to minor increases in surface cover associated with cover crops.

“SEP” stands for soil enrichment protocol. The SEP version 1.0 and supporting documents, including requirements and guidance, (incorporated by reference herein) can be found online at https://www.climateactionreserve.org/how/protocols/soil-enrichment/. As is known in the art, SEP is an example of a carbon registry methodology, but it will be appreciated that other registries having other registry methodologies (e.g., carbon, water usage, etc.) may be used, such as the Verified Carbon Standard VM0042 Methodology for Improved Agricultural Land Management, v1.0 (incorporated by reference herein), which can be found online at https://verra.org/methodology/vm0042-methodology-for-improved-agricultural-land-management-v1-0/. The Verified Carbon Standard methodology quantifies the greenhouse gas (GHG) emission reductions and soil organic carbon (SOC) removals resulting from the adoption of improved agricultural land management (ALM) practices. Such practices include, but are not limited to, reductions in fertilizer application and tillage, and improvements in water management, residue management, cash crop and cover crop planting and harvest, and grazing practices.

“LRR” refers to a Land Resource Region, which is a geographical area made up of an aggregation of Major Land Resource Areas (MLRA) with similar characteristics.

DayCent is a daily time series biogeochemical model that simulates fluxes of carbon and nitrogen between the atmosphere, vegetation, and soil. It is a daily version of the CENTURY biogeochemical model. Model inputs include daily maximum/minimum air temperature and precipitation, surface soil texture class, and land cover/use data. Model outputs include daily fluxes of various N-gas species (e.g., N2O, NOx, N2); daily CO2 flux from heterotrophic soil respiration; soil organic C and N; net primary productivity; daily water and nitrate (NO3) leaching, and other ecosystem parameters.

### Automated Boundary Review Logic

Boundary Review Output is Effectively Split into Two Parts:
1. An overall pass/fail decision for the boundary as a whole, which can be made either by the automated system or by a human reviewer.
2. Review metadata, which is always generated by the automated system. This includes whether the boundary passed or failed each individual check (see “Criteria” section below), as well as some extra details about why it passed or failed those checks. For at least two checks, the automated system response also returns the ineligible geometry, which becomes a recommended correction to the boundary, surfaced directly in the customer interface to prompt the user to accept the newly eligible boundary.

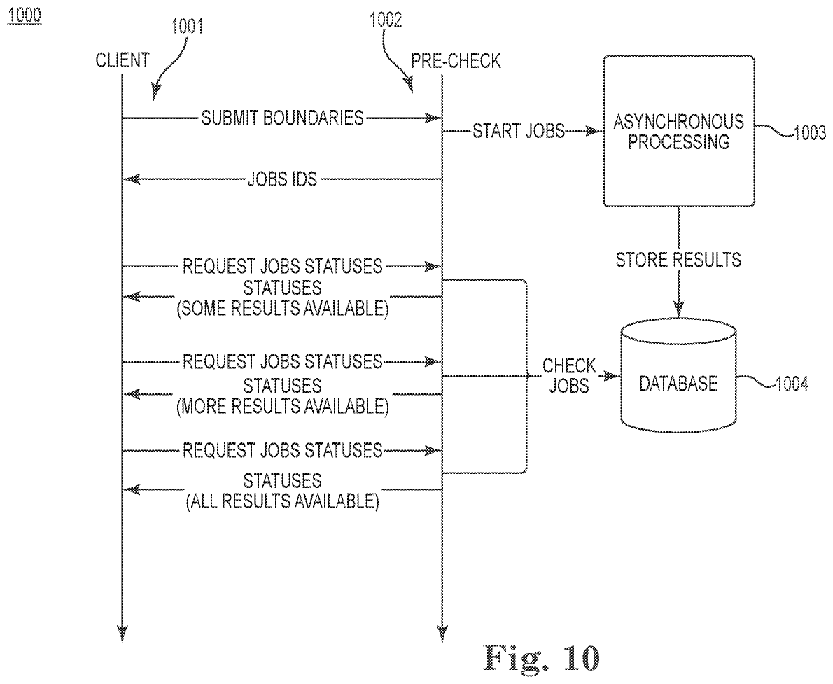

In some embodiments, the boundary check logic is used to calculate the ineligible area and propose a replacement boundary, optionally with justification of the ineligible rationale. This process is shown in FIGS. 10-14, described below.

In some embodiments, human reviewers may be allowed to override the overall pass/fail decision of automated boundary review. Exemplary situations in which the system may be configured so human decisions take precedence over automated ones:
1. If the current version of a field boundary was reviewed by a human, the auto review system will not override the human decision if the auto review re-reviews the same version of that field boundary. If the boundary is updated, however, the auto review system is allowed to make the pass/fail decision for the new version.
2. If any previous version of a field boundary was ever failed by a human, all future versions will need to be reviewed by a human.

In some embodiments, if the auto review system is not allowed to override an overall pass/fail decision made by a human, it will still create or update the metadata for that boundary to ensure it's available and in line with the latest review logic.

In some embodiments, the auto review system may override a boundary review checked by a human. In some embodiments, the auto review system may be applied to one or more eligibility criteria (e.g. checks). For example, the auto review system may be applied to fewer than all of the eligibility criteria (including for example, a subset of eligibility criteria. In another example, the auto review system may be applied only to: those criteria last updated after a specified date (e.g. criteria not updated within the last 5 years, 2 years, 1 year, 6 months, 1 month, 1 week, 1 day, 1 hour, etc.), those criteria which have not previously been reviewed by a human, those criteria which have not been reviewed by a human within the last 5 years, 2 years, 1 year, 6 months, 1 month, 1 week, 1 day, 1 hour, etc., those criteria including data types directly received from a user, those criteria not including data types directly received from a user, and or those criteria which have not previously been subjected to auto review. For example, if a federal land check was added to the automated system after review had been completed (e.g. by humans or the automated system or both) the auto review system would automatically review all current boundaries for compliance with the requirements of the federal land check regardless of the previous review status of the boundaries.

### How Reviews Happen

When a field boundary is created or updated, a review task for that boundary is automatically generated (without human intervention) within the auto review system. In some embodiments, the result of the review automatically generates a modified user interface of a client device. For example a modified user interface of a client device may comprise one or more of the following: an icon indicating compliance or non-compliance of the boundary with one or more checks, a modal indicating compliance or non-compliance of the boundary with one or more checks, a modal requesting additional user input based on compliance or non-compliance (or a probability of compliance or non-compliance) of the boundary with one or more checks, compliance or non-compliance of the boundary with one or more checks, an updated field boundary displayed on a map (optionally, additionally indicating one or more compliant or non-compliant regions of the boundary), an icon comprising a polygon representing the shape of the field boundary or updated field boundary). In some embodiments, the updated field boundary displayed on a map comprises coloration corresponding to a probability of compliance or non-compliance with one or more checks of the boundary, a region of the boundary, or a region within the boundary, checks only take a couple of seconds to run in normal circumstances, review results should be available within a very short time of the field boundary update.

In situations where something goes wrong during the review process, some combination of responses may be provided, including: automated retries, automatic notification to the user (for example, with a prompt to correct missing or out of range values), alerting oncall engineers to manually troubleshoot, and/or a regularly scheduled job to review any boundaries that have failed or been missed.

### Exemplary Criteria

Cropland Data Layer check

The cropland data layer check reviews development status or use associated with a boundary. In some embodiments, the check raises an error to a user if the development status or use detected within a boundary by the auto review system differs from a user submitted value or reference data. In some embodiments, development status or use detected within a boundary by the auto review system is predicted from automated analysis of remote sensing data of the boundary.

In some embodiments, the USDA Cropland Data Layer (CDL) is used to determine if a boundary contains land that would make it ineligible. In some embodiments, a machine learning model is trained on a data set of remote sensing data and corresponding CDL classes to determine a classifier for land use (e.g. detection of industrial or residential buildings, roads, parking lots, open water, fallow land, forest, non-agricultural uses, etc.). In some embodiments, an automated procedure for the selection of the optimal decision threshold is applied to the classification algorithm (e.g. generalized threshold shifting (GHOST)). In some embodiments, if a single 30×30 meter “pixel” of any ineligible CDL class (e.g. Developed, Developed/Med Intensity, Developed/High Intensity, Open Water, Aquaculture, etc.) is present within a boundary, that boundary is automatically categorized as non-compliant and returned to the user for attestation or resubmission or flagged for manual review.

The CDL is a yearly dataset, with new versions for the previous year generally published in January. In various embodiments, CDL data is provided via an API endpoint in the form of a “zonal summary,” which is a table of the classes found within the boundary and the number of pixels of each class that are present within the boundary. The position of these pixels within the boundary is not included.

When requesting CDL data the desired year is specified. In some embodiments this is hard-coded to the most recent year available and will need to be updated every year. In other embodiments, the desired year is determined automatically based on the issuance (e.g. of an ecosystem credit or sustainability claim). In such embodiments, it is necessary to verify that the year in question has actually been published.

In some embodiments, before performing zonal summaries, the boundary is “buffered” (shrank) inwards by 30 meters on all sides to avoid false positives caused by the limits of CDL data accuracy.

In some embodiments, the remote sensing algorithms use data that have been summarized for each field boundary. This process (called zonal summary) converts time series data from many thousands of individual granules (individual raster files) into a single data frame (e.g. that is stored as a text file on AWS S3), where each row is a single time series observation for a single boundary polygon record. The resulting data set consists of time series of zonal summaries for each input feature (remotely sensed measurement, weather variable) for each field.

More generally, to provide data suitable for analysis, it is desirable to transformation from raster data to columnar data. A zonal summary fills this need, and an exemplary embodiment is described below.

An exemplary method of generating a zonal summary follows. A set of polygons is read. The set of polygons may be, e.g., countries, states, countries, fields, zip codes, etc.). A raster products is read. The raster product may be any of a variety of raster remote sensing products as described herein. A set of valid pixels is extracted for each day in a period of interest. A valid pixel is, e.g., one that is not covered by clouds. The distribution of pixel values for each polygon is determined. The distribution is reduced to a set of representative values, e.g., minimum, maximum, mean, etc. A table or other data structure is generated for each polygon. In an exemplary table, each row has columns for the id of the polygon, the date (or date and time) of the observation, the number of valid pixels in that observation, and the summary statistics (min/max/mean/etc.)

Zonal summaries make remote sensing data legible for machine learning, business analytics, and simple visualization. Along the way, they reduce the data consumers need to process by a factor of 1,000,000.

In some embodiments, data for a given field boundary may not require summarization. For example, where a data set is time invariant, or has low variation at the field level, summarization may be unnecessary.

### Federal Land Check

Federal land ownership is checked using the USGS Protected Areas Database (PAD). If a boundary overlaps with an area in this database that has the feature class “fee” and manager type “FED” (federal), it is considered to be on federal land.

The USGS does not make any guarantees about the accuracy of the PAD, so just as for the CDL checks, the boundary is optionally buffered inwards by 30 meters before looking for overlaps to avoid false positives caused by data accuracy limits. In some embodiments, upon a boundary being determined not to be in compliance, a notification is automatically sent to a client device (e.g. a graphical user interface of a client device is modified to accept one or more piece of evidence (e.g. a time stamped and georeferenced photograph or video)). In some embodiments, receipt of evidence from independent parties or receipt of more than one type of evidence results in automatic update to the status of a region and or a change in the probability of a compliance or non-compliance determination for the relevant criteria and or geography. For example, at least one case exists where the geometry of a national park as defined in the database but is off by over two miles compared to the park's own maps. In this example, a non-compliant boundary overlapping with the two mile area falsely identified as national park triggers an automatic modification of the graphical user interface of a client device configured to accept one or more pieces of evidence contradicting the reason for non-compliance. Exemplary evidence that could be submitted through the modified user interface include, a map of the national park with a date or version number and geographic coordinates for the park boundary, a georeferenced video recording of the park boundary (e.g. displaying boundary markers), georeferenced photographs of boundary markers of the park boundary, etc.

In alternative embodiments, the CDL check only identifies a boundary for as non-compliant if (a) at least two different classes are present and (b) together they make up at least a threshold percentage (e.g. 1% or greater) of the boundary's total area. Examples of classes that trigger non-compliance only if observed together or in more than a percentage of the total area of a boundary include: developed/open space, developed/low intensity, grass/pasture, and fallow/idle cropland.

Additional checks include boundaries for buildings, roads, and waterways using, for example, the Bing Buildings, OSM Water and Waterways, and TIGER 2015 Roads datasets.

A variety of remote sensing techniques may be applied to determine characteristics of a given geography, which may be used in turn to perform boundary verification and adjustment. Examples are provided below.

### Crop Type Classification

In some embodiments, the check raises an error to a user if the crop type detected within a boundary by the auto review system differs from a user submitted value (e.g. a user submitted crop type or a crop management practice (e.g. a crop rotation, planting or harvesting date, etc.)) that is inconsistent with user submitted data, reference data, or predicted data (for example, from automated analysis of remote sensing data) of the boundary. In some embodiments, a machine learning model is trained on a data set of remote sensing data and or historical data to determine a classifier for crop type. Crop type describes the species of crop that a grower plants during the growing season. The United States government provides annual maps of crop type called the Cropland Data Layer (CDL). The maps come out in February and describe crops harvested during the previous calendar year. There is a need to estimate crop type during the season, well before the CDL comes out in the following year.

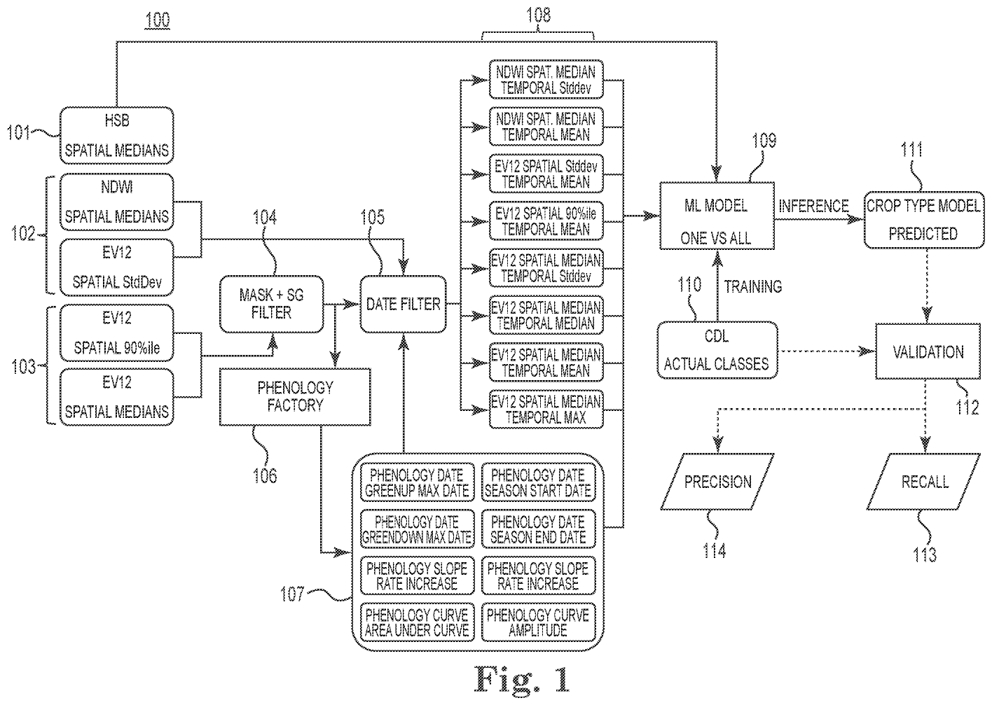

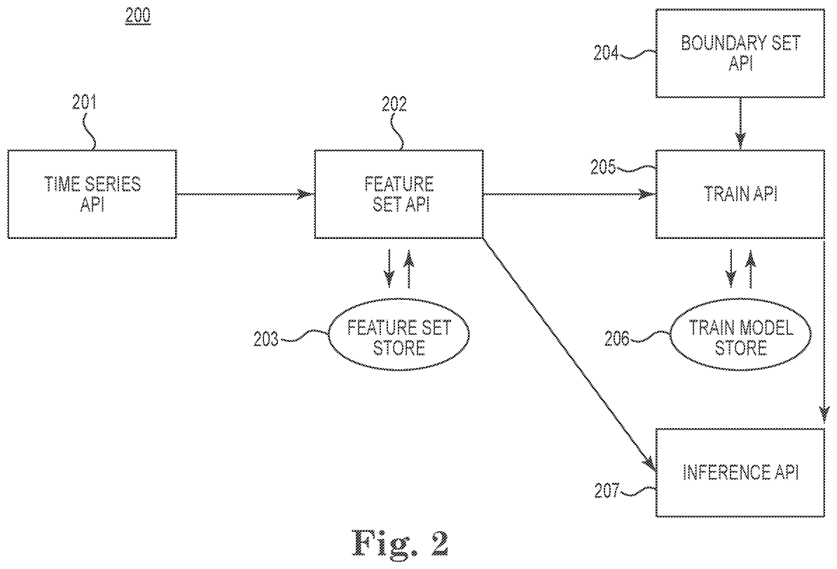

An exemplary crop type classification method is illustrated in FIGS. 1-2.

FIG. 1 shows an exemplary embodiment of a crop type classification method 100. Within crop type classification method 100, various inputs 101, 102, and 103 are provided to machine learning model 109. Input 101 may comprise a Historical Sequence Base (HSB) method output time series of one or more spatial medians. Inputs 102 may comprise the spatial median output of a normalized difference water index (NDWI) and/or a spatial standard deviation of an enhanced vegetation index (EVI2). Inputs 102 may be provided to a date filter 105. The date filter 105 filters the temporal data inputs to a desired timeframe, and provides a filtered output 108. Inputs 103 may comprise a spatial 90^{th} percentile of an EVI2, and/or spatial medians of EVI2. Input 103 may be filtered and masked by mask and Savitzky-Golay (SG) filter 104, the filtered output of which is provided to the date filter 105 and/or the Phenology Factory 106. Within the Phenology Factory 106, data is taken from each input and sorted into a phenology set 107. The phenology set 107 can comprise a phenology date including a greenup max date, a season start date, a greendown max date, and/or a season end date. The phenology set 107 can further comprise a phenology slope (a rate increase or decrease), or a phenology curve (the area under the curve or amplitude).

Both the phenology set 107 and the filtered outputs 108 may be provided to the machine learning model 109. The output from the machine learning model 109 determines a predicted crop type model 111.

During training, CDL 110 is used to provide training data in the form of actual classes to the machine learning model 109. The predicted crop type 111 can be used for validation 112, yielding a recall output 113 and a precision output 114.

FIG. 2 shows an exemplary embodiment of a crop type classification system 200. In crop type classification system 200, a time series API 201 invokes a feature set API 202. The feature set API 202 can communicate with a feature set store 203, where a set of commands or information is passed between the two modules. The feature set API 202 and boundary set API 204 invoke training API 205. Training model store 206 stores and retrieves training models. An additional inference API 207 is invoked by the feature set API 202 and training API 205.

Crop type classification is the task of labeling the crop species over a given time period. Typically, planted crop area is estimated as opposed to harvested area. Models of some embodiments of the present disclosure are constrained to field data or ancillary products of crop type and, therefore, are trained to estimated planted area.

### In-Season Model

The crop type classification model according to various embodiments can be used to generate in- or end-of-season estimates of planted crop species. For in-season estimates, vegetation indices are forecasted from the current, in-season date to the end of season. Thus, in-season predictions can technically be made at any point during the season. End-of-season estimates do not require forecasts.

### Training Inputs and Pre-Processing

In some embodiments, a multi-year time series of field-level greenness observations and associated crop labels from the USDA Cropland Data Layer (CDL) are used for training inputs and pre-processing.

### Features and Labels

Features are generated for each season (i.e., 12-month period from 1 January to 1 January) using HLS time series. Crop species labels are automatically collected from overlapping CDL estimates. Currently, for a given county crop species labels are collected across the entirety of the county plus any neighboring county. Therefore, the vector of crop species that can be estimated later in the process is restricted to those that exist in the CDL product across in the multi-county collection.

The CDL product is used to generate large training datasets for anywhere in the US. However, these labels can be enhanced or replaced with field data.

A minimum sample threshold is used to filter crop species with inefficient representation across the county, or counties.

TABLE 1
Predictive features and labels used to estimate crop type:

| | | | | | | Labels (y) |
|---|---|---|---|---|---|---|
| | | | | | | USDA |
| Predictive variables (X) | | | | | | Cropland |
| EVI2 | NDWI | Extracted pheno-metrics using EVI2 | | | | Data Layer |
| {μ, σ, 50^{th}, max} | {μ, σ, 50^{th}, max} | Area | Amplitude | Rates of | Season | Labels |
| | | under | | increase \| | dates \| | depend on |
| | | curve | | decrease | stages | training |
| | | | | | | region |

The timing and rates of green-up and green-down are detected using a double logistic function:

$$y = m 1 + ( m 2 - m 7 * x ) * ( ( 1. / ( 1. + exp ( ( m 3 - x ) / m 4 ) ) ) - ( 1. / ( 1. + exp ( ( m 5 - x ) / m 6 ) ) ) )$$

TABLE 2
Logistic Function Coefficients

| Coefficient | Description |
|---|---|
| m1 | Time series background value |
| m2 | Time series amplitude |
| m3 | Spring day of onset |
| m4 | Spring change rate |
| m5 | Autumn offset |
| m6 | Autumn change rate |
| m7 | Summer green-down |

### Forecasters

Regardless of whether an in- or end-of-season crop type is predicted, the classifier used (next section) works best with a full season of date.

Note that the definition of season that is currently being used is based on a 12-month agricultural season (1 January to 1 January in the US). Some embodiments of this algorithm may include more nuanced seasonal estimates defined by phenology.

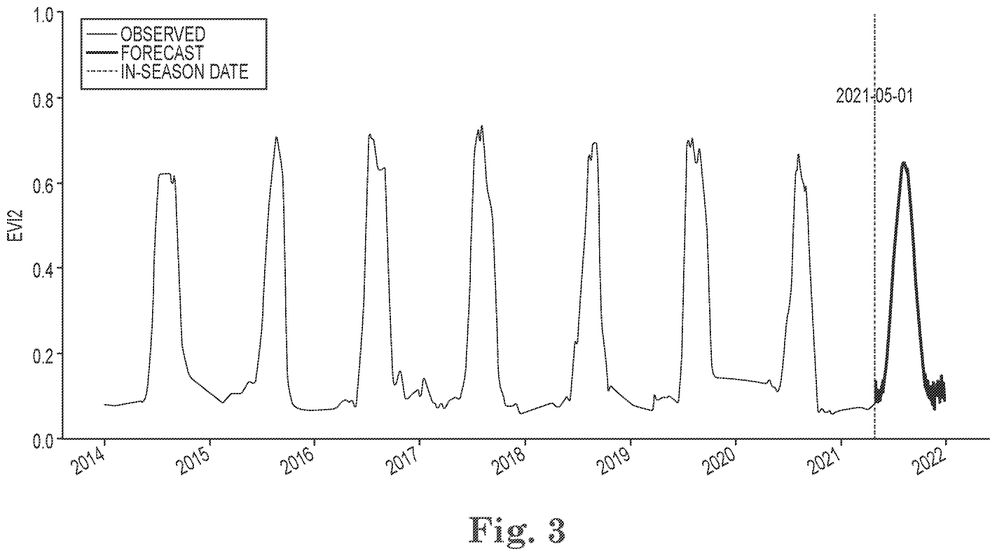

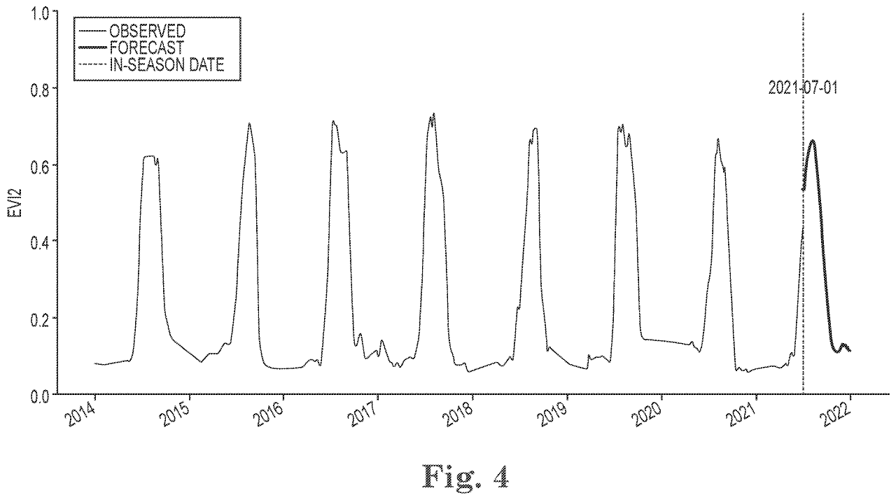

For in-season models, two forecasters are trained on the EVI2 and NDWI time series, using the most recent year with complete time series. As an example, assume there is interest in estimating 2022 crop species starting 1 May 2022 (FIG. 3). Input data might have HLS observations from 1 Jan. 2014 to 1 May 2022 and associated annual CDL estimates from 2014 to 2021 as crop-species labels. Two forecast models (one for each index) would be trained using data from 1 Jan. 2014 to 1 May 2021 and used to forecast the vegetation index signal from 1 May 2021 up to 1 Jan. 2022. These models are saved to file and later used for in-season forecasting (more details in the following section). FIG. 4 illustrates the same process at a later in-season date (i.e. 1 Jul. 2021).

For forecasts, the PyTorch Forecasting module is used in some embodiments with the N-BEATS method, which is a supervised forecasting method. In particular, N-BEATS is a deep learning model that recreates the mechanisms of statistical models using double residual stacks of fully connected layers. Thus, years in the time series preceding a target are used, with in-season dates to learn time series patterns in order to forecast the signals. One disadvantage of this method is that it cannot optimize using covariates. Therefore, a separate forecaster on each VI (for now, EVI2 and NDWI) is trained.

While certain embodiments employ N-BEATS, it will be appreciated that a variety of alternative time-series forecasting methods may use used, such as ES-RNN.

### Classifier

In addition to the forecast models, a classification model is trained on the pooled dataset that consists of observations up to the most recent year of crop labels (i.e., latest CDL release). Using the example from the section above, the classifier would be trained on pooled data (features+labels) from 1 Jan. 2014 up to 1 Jan. 2022.

Because the data are pooled across years, the classifier does not currently use temporal dependencies (or, sequence-based models) for optimization. However, it is contemplated that this would improve estimates compared to some embodiments of the algorithm. Examples of sequence-based classifiers include Indigo's HSB method, conditional random fields (CRF), and recurrent neural networks (RNN).

In some embodiments, the LightGBM classifier is used to estimate crop species. However, it will be appreciated that a variety of classifiers may be used in alternative embodiments, including other gradient boosting models.

### Predictions

Predictions are applied to a single season (12-month period) to estimate crop type. If the target date is in-season then forecasts are applied prior to classification inference. Again following the example described above, for an in-season target date of 1 May 2022, the trained forecasters for each VI would be applied to 1 Jan. 2015 (shifted +1 year) to 1 May 2022 time series in order to forecast the vegetation signal throughout the rest of the calendar year. Following in-season vegetation index forecasts, the classifier is then applied to the target season (2022 in this example) to estimate crop species. FIG. 3 is a graph illustrating the estimation of a 2022 crop species, according to one or more aspects of the present disclosure. FIG. 4 is an illustration of the same estimation of a 2022 crop species at a later in-season date, according to one or more aspects of the present disclosure.

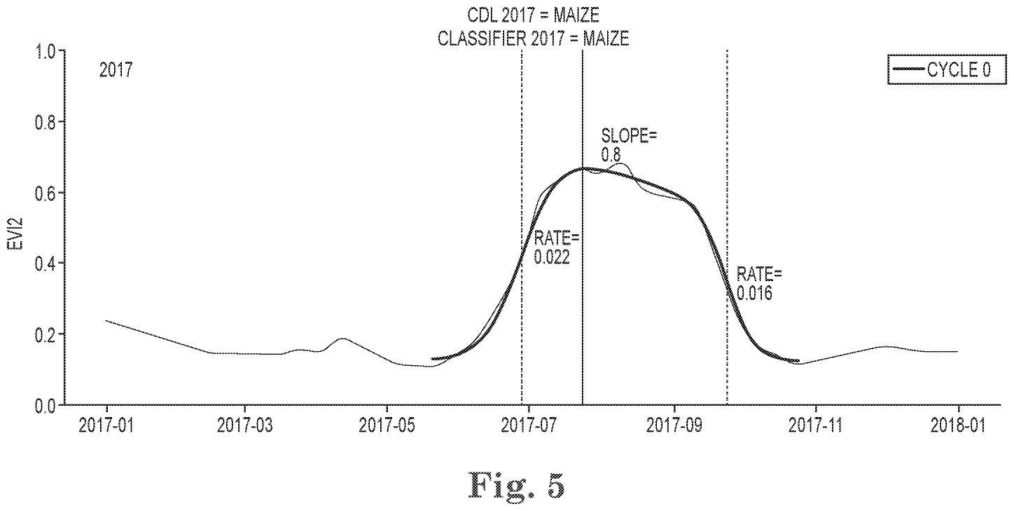

Exemplary results are provided in FIGS. 5-9.

FIG. 5 illustrates the results for the process as described applied to the maize crop of 2017 over a year long cycle. The cycle 0 prediction is overlayed on the graph with the slope and rates displayed for main segments of interest within the cycle.

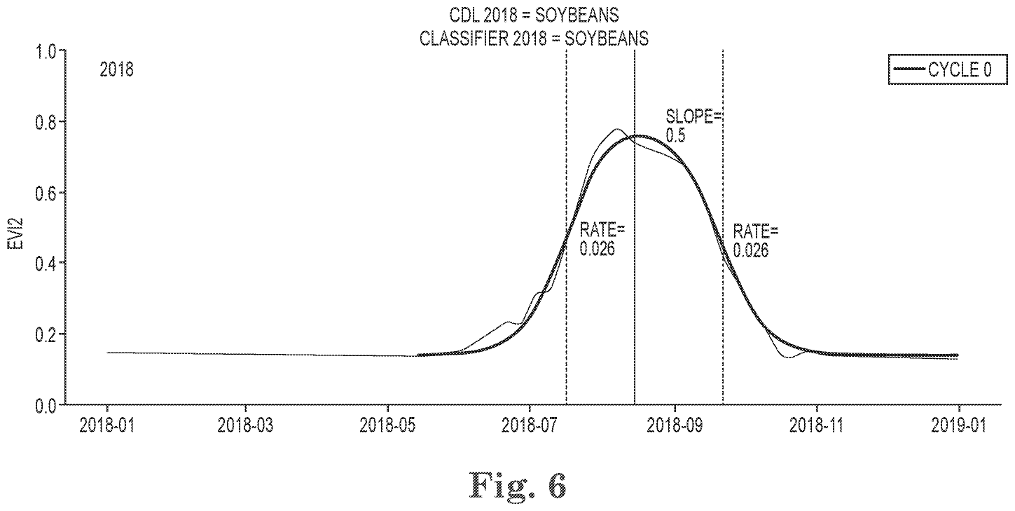

FIG. 6 illustrates the results for the process as described applied to the soybean crop of 2018 over a year long cycle. The cycle 0 prediction is overlayed on the graph with the slope and rates displayed for main segments of interest within the cycle.

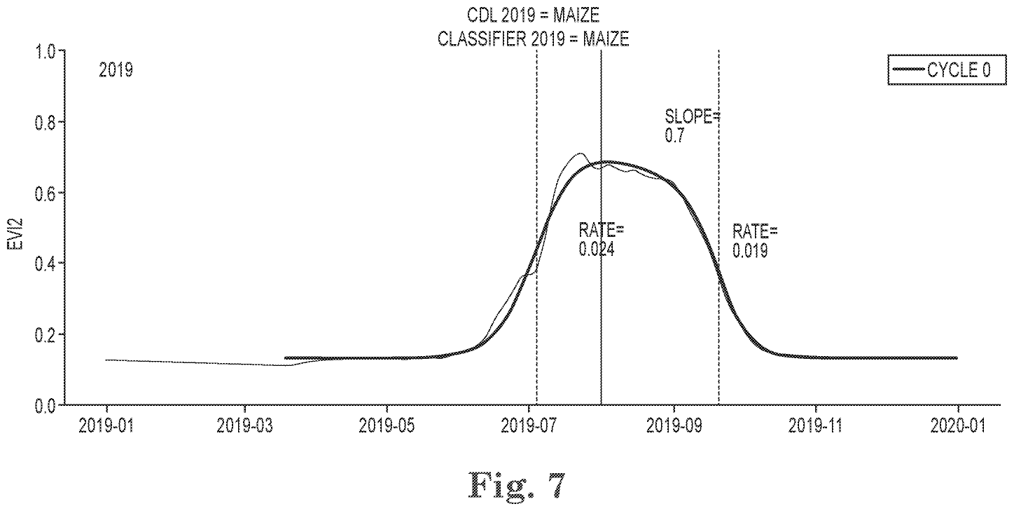

FIG. 7 illustrates the results for the process as described applied to the maize crop of 2019 over a year long cycle. The cycle 0 prediction is overlayed on the graph with the slope and rates displayed for main segments of interest within the cycle.

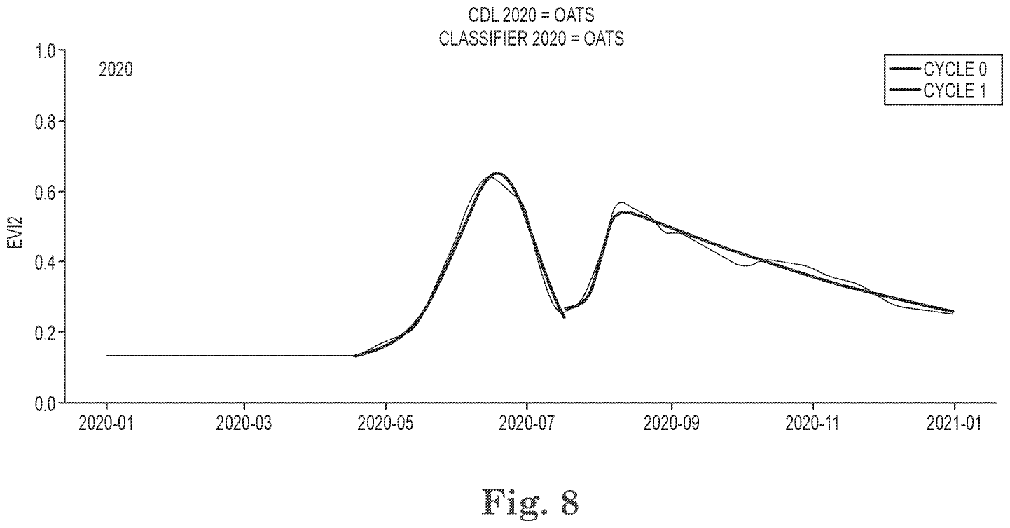

FIG. 8 illustrates the results for the process as described applied to the oat crop of 2020 over a year long cycle. The cycle 0 and cycle 1 predictions are overlayed on the graph displaying the EVI2 values within the cycle.

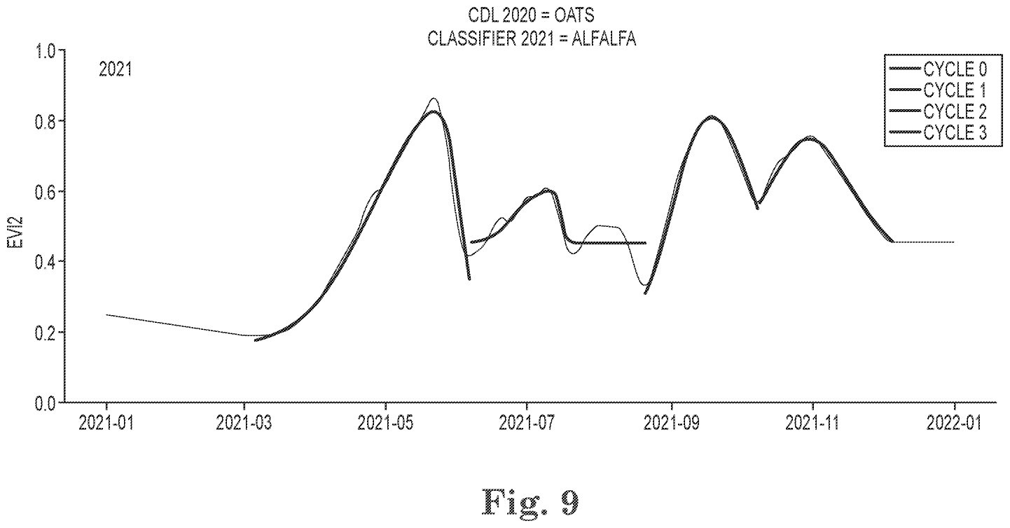

FIG. 9 illustrates the results for the process as described applied to the oat and alfalfa crops of 2021 over a year long cycle. The cycle 0, 1, 2, and 3 predictions are overlayed on the graph.

### Flooding Algorithm

In various embodiments, a simple thresholding approach is used to detect surface water based on HLS inputs (red, NDVI, SWIR2). There is strong light absorption by liquid water in the SWIR (low reflectance). By thresholding for low values of both NDVI and SWIR, regions with high liquid water content but not from the presence of green vegetation are targeted. An additional threshold for low values of visible Red in winter months helps screen out highly reflective snow. It will be appreciated that alternative flood detection algorithms may be used in place of thresholding, including various machine learning models trained on remote sensing data.

In various embodiments, features include:
Interpolation of all gaps in HLS record.
Decision tree based on NDVI and Red bands, with placeholder for NDWI
Included SWIR2 band and removal of NDWI placeholder
Introduced gap limits to interpolation of HLS time series
Definition of “events” (see FloodEvents class)
Interpretation of sparse daily classified observations as flood events. Anomalous conditions with snapshots are detected, thus assumptions about duration of flooding are made.

In various embodiments, after limited interpolation of HLS time series, periods of contiguous classified flooding are summarized as a dataframe, with estimated start_date and end_date and # associated observations. Events that are close together in time (gaps within X days, specified in FloodParams) are assumed to be associated with a single event and are merged together. Once events are defined with start_date and end_date, a reverse operation is performed that counts # of estimated days that were flooded each monthly per year

### Outputs Include:

Dataframe indexed by geo_id, year
   Three primary monthly metrics to all months:
      flooded_days (# of estimated flooded days) for all months, January-December
      flooded_obs (# of flooded observations) for all months January-December
num_obs (# of total observations) for all months, January-December
   Total annual summaries of same metrics:
   Events details on any events that occur in given year (including start_date, end_date, n_obs, duration)
      This column can be parsed using flooding.transform_events (df)
columns (42 total)
   geo_id [str]
   year [int]
   flooded_days_Jan:flooded_days_Dec [int]
   flooded_obs_Jan:flooded_obs_Dec [int]
   num_obs_Jan:num_obs_Dec [int]
   total_flooded_days [int]
   total_flooded_obs [int]
   total_obs [int]
   events [str, representation of dict that can be transformed to a separate events df]

In various embodiments, daily MODIS (or MWP) are included. MODIS NBAR, smoothed over 16-day window, is not nearly as sensitive to flooded conditions—particularly the short events that the HLS record is missing. If the daily MODIS (or the existing NRT MODIS Water Product, MWP) can be used, this helps to capture these ephemeral conditions: Snow melt in higher latitudes; Acute/brief flood events: (eg. Midland, MI Dam Breach in May 2020).

An exemplary process for a pre-check API workflow is shown in FIG. 10, in accordance with one or more embodiments of the disclosure. The boundary pre-check process as illustrated supports json over HTTPS, and in an exemplary implementation can process up to 500 boundaries per API call. The workflow can be asynchronous; in the first call, a list of boundaries is submitted. On the backend, a “pre-check job” is created for each boundary and returns the job IDs. Subsequent calls are made to check on the status of the job and to collect the eligibility information.

FIG. 10 illustrates an exemplary workflow 1000 between a client side 1001 and a pre-check provider 1002. From the client side 1001, boundaries are submitted and job IDs are sent in return from the pre-check provider 1002. The client side 1001 may request job statuses at least once, where the pre-check provider 1002 returns some or more results as available. This is continued until all results are available and sent to the client side 1001. When the client initially submits boundaries, the pre-check provider 1002 starts jobs at an asynchronous processing module 1003. Results are stored, then sent to database 1004. When the client side 1001 requests job statuses, the pre-check 1002 checks jobs then sends each to the database 1004.

### Authorization/Authentication and Security

A user will receive an API token for production and testing, and will place the API token in the authentication header following the pattern Authorization: bearer <token> when making requests to the pre-check API.

These tokens are kept secure by the user within the user's back-end infrastructure. The tokens are not intended to be delivered to a browser and requests are not intended to be made from a browser to the API to ensure the token is not compromised.

### Usage

Two endpoints are supported: production and testing. First, the user creates a POST/boundaries/review, providing the list of boundaries, each with a unique ID from the user system with geojson representing the field boundary. The API returns a list of pre-check job IDs. Next, the user makes (potentially many) POST/boundaries/review/status calls providing a list of job IDs as input. The pre-check API returns a list of jobs. Each job has a status:
1. Working: the boundary is still being processed, try again later.
2. Error: an issue has arisen on the API side.
3. Complete: the job is done, check the ineligibility_reasons attribute (shown in Table 3). If the list is empty, the field is eligible.
4. not_found: The job ID requested does not exist, either the user made a mistake or the request has been removed from the API for some reason (such as to save database space).

Depending on use case, the user can poll the boundaries/review/status endpoint every few seconds (for example, to display incremental results) or wait and made one call (for example, to process large volumes of boundaries overnight).

### Exemplary Limits and SLAs

1. The average boundary review request takes 170 milliseconds; a batch of 500 jobs will take 1 minute 25 seconds on average.
2. Only 500 boundaries can be under review at a given time per API token.
3. No pre-check job will take more than 15 minutes. The job will end up in status error after this time.
4. No more than 30,000 boundary statuses requested per minute from the/boundaries/review/status endpoint. This could be one call per second with 500 job IDs specified, or one call every 2 milliseconds with 1 job ID specified, or anything in between, so long as no more than 30K boundaries are requested a minute

TABLE 3
Exemplary Issue Types

| Code | Issue Type | Meaning |
|---|---|---|
| TOO_LARGE | Geometry | The |
| | | geometry |
| | | either has too |
| | | much land |
| | | area (100,000 |
| | | hectares or |
| | | 247,000 acres |
| | | in a single |
| | | field |
| | | boundary) |
| | | OR is either |
| | | too long in |
| | | the east/west |
| | | or |
| | | north/south |
| | | axis (10 |
| | | kilometers) |
| TOO_MANY_POINTS | Geometry | The |
| | | geometry has |
| | | over 3000 |
| | | coordinate |
| | | points. |
| TOO_MANY_POLYGONS | Geometry | The |
| | | geometry is a |
| | | MultiPolygon |
| | | and has over |
| | | 50 child |
| | | polygons. |
| LATITUDE_TOO_HIGH | Geometry | A coordinate |
| | | in the |
| | | geometry is |
| | | above 90 |
| | | degrees |
| | | latitude |
| LATTITUDE_TOO_LOW | Geometry | A coordinate |
| | | in the |
| | | geometry is |
| | | below −90 |
| | | degrees |
| | | latitude. |
| TOO_POUROUS | Geometry | The area of |
| | | the convex |
| | | hull of the |
| | | geometry is |
| | | 100 times |
| | | greater than |
| | | the area of |
| | | the geometry. |
| LAND_TYPE | Non-compliance | The |
| | with | geometry |
| | methodology | contains land |
| | requirements | that has had |
| | | uses other |
| | | than |
| | | cropland. |
| | | This may |
| | | sometimes |
| | | also mean |
| | | that land type |
| | | data is |
| | | unavailable; |
| | | double check |
| | | that the |
| | | boundary is |
| | | on land and |
| | | in the |
| | | continental |
| | | United |
| | | States. |
| FEDERAL_LAND | Non-compliance | The |
| | with | geometry |
| | methodology | overlaps with |
| | requirements | federal lands. |
| | | The response |
| | | may have the |
| | | geometry of |
| | | the federal |
| | | lands for |
| | | comparison |
| | | with the |
| | | submitted |
| | | geometry. |
| HISTOSOLS_PRESENT | Non-compliance | The |
| | with | geometry |
| | methodology | contains |
| | requirements | histosols, |
| | | peaty soils |
| | | that already |
| | | have an |
| | | incredibly |
| | | high |
| | | concentration |
| | | of carbon and |
| | | are not |
| | | eligible for |
| | | carbon credit |
| | | production. |
| WETLANDS_PRESENT | Non-compliance | The |
| | with | geometry |
| | methodology | contains |
| | requirements | wetlands in |
| | | the US |
| | | national |
| | | wetland |
| | | inventory. |
| LAND_CONVERSION | Non-compliance | The |
| | with | geometry |
| | methodology | contains land |
| | requirements | that has been |
| | | converted to |
| | | cropland |
| | | from other |
| | | uses in the |
| | | last 10 years. |
| HIGHLY_ERODIBLE_PRESENT | Non-compliance | Areas in the |
| | with | geometry are |
| | methodology | susceptible to |
| | requirements | erosion, |
| | | typically |
| | | because of |
| | | the slope of |
| | | the land |
| | | contained |
| | | within the |
| | | geometry. |
| ADMINISTRATIVE_BOUNDARY_NOT_SUPPORTED | Non-compliance | Areas in the |
| | with | geometry |
| | methodology | contain land |
| | requirements | that is not |
| | | eligible per |
| | | methodology, |
| | | e.g., states, |
| | | countries, or |
| | | territories |
| | | where the |
| | | program is |
| | | not active. |

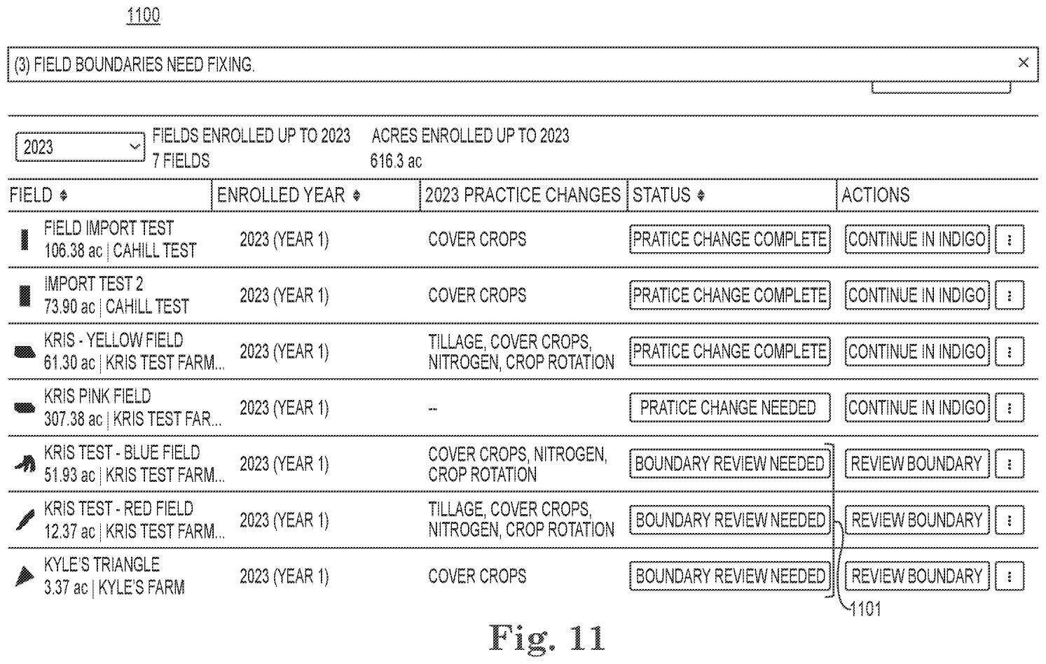

Various options to resolve issues identified by the auto review system include one or more of: analysis of remote sensing data to predict one or more compliant geometries for the identified region (optionally, automatically modifying a user interface of a client device to present one or more of the predicted compliant geometries for selection or editing within the user interface), modifying a user interface of a client device to present remote sensing imagery of a region comprising the submitted boundary wherein such interface is configured to accept user input of a newly drawn boundary or modification of the user submitted boundary), automatic trimming of the non-compliant region from the submitted boundary, return of the ineligible region of the submitted boundary, and automatically modifying a user interface of a client device to accept an attestation of a user (e.g. a model comprising text input or option to select text, an audio recording, a video or picture, official documentation, etc.). FIG. 11 is an exemplary display 1100 of a customer leveraging the API. Here, several field boundaries 1101 have been identified as needing fixing by the system. The status of each of the fields is associated with a color indicator, and details about each field are also displayed, including the field shape, acreage, enrolled year, practice changes, and actions. Actions include “continue in Indigo” or “Review boundary.” The user is able to select the action indicator to review the boundary as necessary.

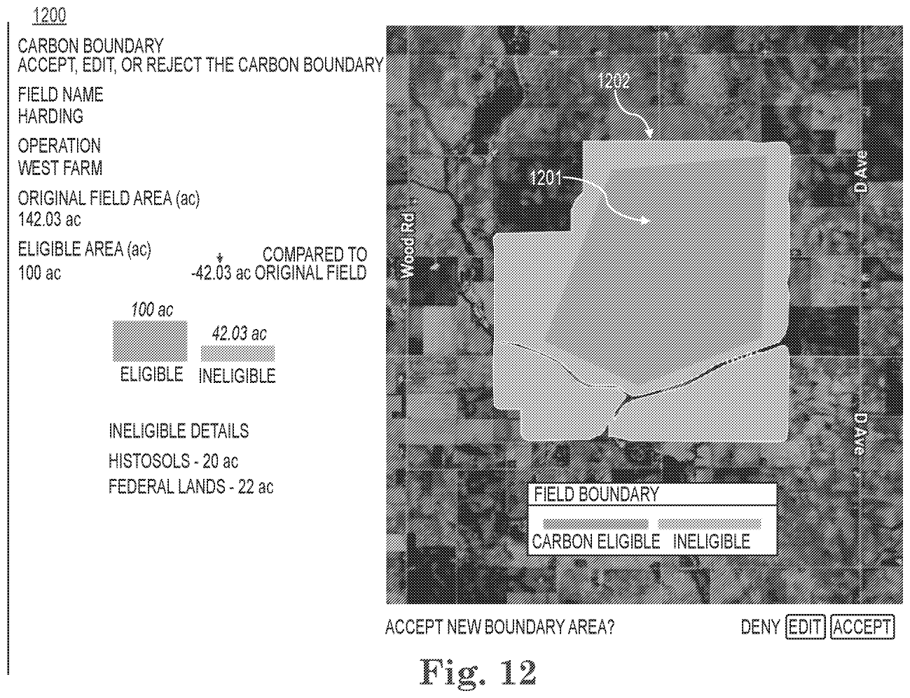

Once the action is selected, the system then shows the exemplary display 1200 in FIG. 12, for example. This exemplary display illustrates the system experience when a grower begins to fix a boundary. This display includes a system-generated field boundary 1201, wherein a subsection 1202 of the field is determined to be carbon eligible. The rest of the field is determined as ineligible. Eligible and ineligible geographic metadata is provided by the API on the backend of the system, data concerning the eligible area is included on the display, which shows a decrease in the eligible area compared to the original boundary of the field. If the user is dissatisfied by the field boundary, the user can select the “deny” option when prompted to accept the new boundary area. If the user is satisfied with the field boundary as defined, or wants to change the field boundary definition, the user can then select the “edit” or “accept” option.

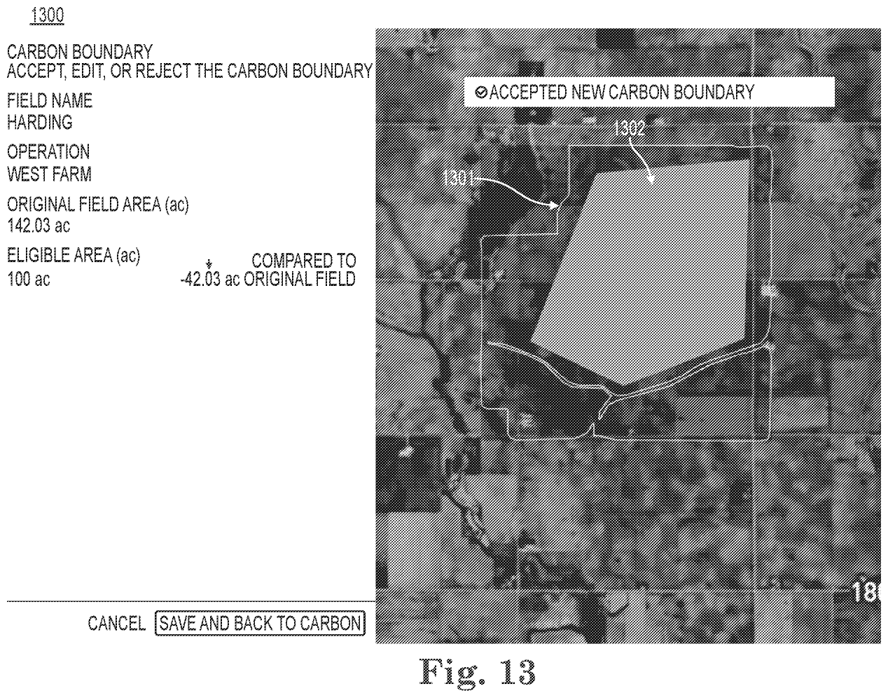

FIG. 13 displays an accepted boundary screen 1300, where the user or grower completes fixing the boundary 1301. Eligible and ineligible geographic metadata is provided by the API on the backend, and the grower is prompted to cancel the accepted dimensions or to save and return to the carbon analysis within the system. The accepted new carbon boundary 1302 is displayed within the boundary 1301, indicating that the boundary has changed.

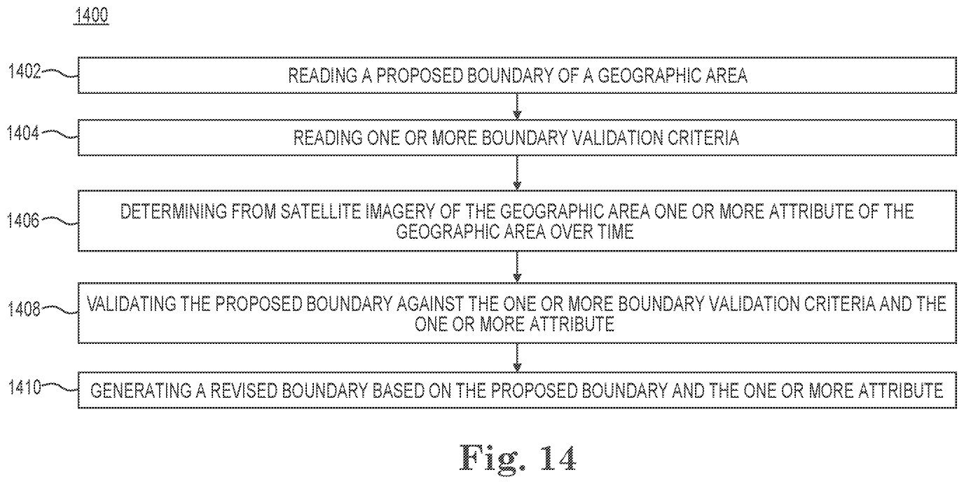

Referring to FIG. 14, a method of boundary verification according to embodiments of the present disclosure is illustrated. At step 1402, the method may include reading a proposed boundary of a geographic area. At step 1404, the method may include reading one or more boundary validation criteria. At step 1406, the method may include determining from satellite imagery of the geographic area, one or more attribute of the geographic area over time. At step 1408, the method may include validating the proposed boundary against the one or more boundary validation criteria and the one or more attribute. At step 1410, the method may include generating a revised boundary based on the proposed boundary and the one or more attribute.

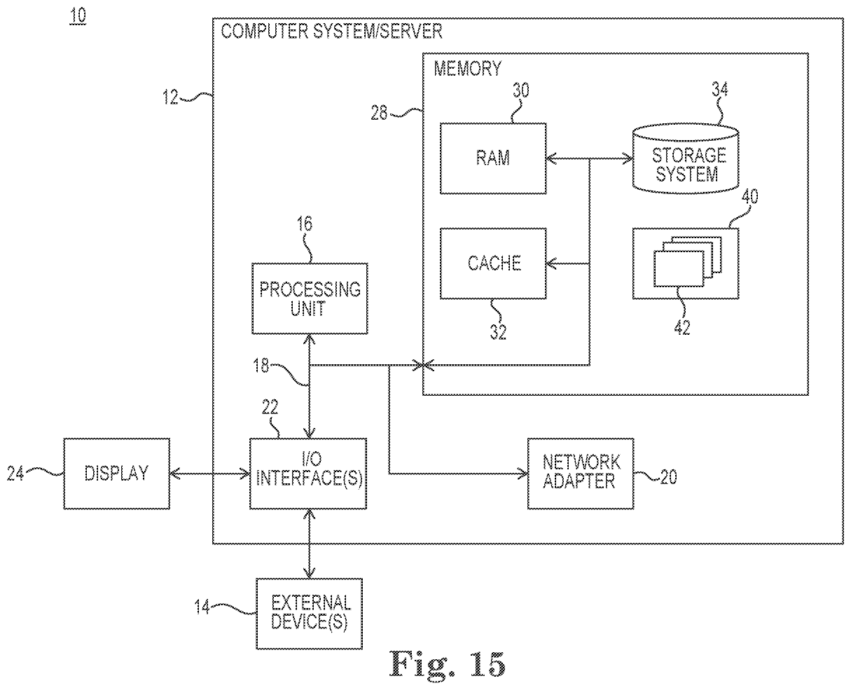

Referring now to FIG. 15, a schematic of an example of a computing node is shown. Computing node 10 is only one example of a suitable computing node and is not intended to suggest any limitation as to the scope of use or functionality of embodiments described herein. Regardless, computing node 10 is capable of being implemented and/or performing any of the functionality set forth hereinabove.

In computing node 10 there is a computer system/server 12, which is operational with numerous other general purpose or special purpose computing system environments or configurations. Examples of well-known computing systems, environments, and/or configurations that may be suitable for use with computer system/server 12 include, but are not limited to, personal computer systems, server computer systems, thin clients, thick clients, handheld or laptop devices, multiprocessor systems, microprocessor-based systems, set top boxes, programmable consumer electronics, network PCs, minicomputer systems, mainframe computer systems, and distributed cloud computing environments that include any of the above systems or devices, and the like.

Computer system/server 12 may be described in the general context of computer system-executable instructions, such as program modules, being executed by a computer system. Generally, program modules may include routines, programs, objects, components, logic, data structures, and so on that perform particular tasks or implement particular abstract data types. Computer system/server 12 may be practiced in distributed cloud computing environments where tasks are performed by remote processing devices that are linked through a communications network. In a distributed cloud computing environment, program modules may be located in both local and remote computer system storage media including memory storage devices.

As shown in FIG. 15, computer system/server 12 in computing node 10 is shown in the form of a general-purpose computing device. The components of computer system/server 12 may include, but are not limited to, one or more processors or processing units 16, a system memory 28, and a bus 18 that couples various system components including system memory 28 to processor 16.

Bus 18 represents one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, Peripheral Component Interconnect (PCI) bus, Peripheral Component Interconnect Express (PCIe), and Advanced Microcontroller Bus Architecture (AMBA).

Computer system/server 12 typically includes a variety of computer system readable media. Such media may be any available media that is accessible by computer system/server 12, and it includes both volatile and non-volatile media, removable and non-removable media.

System memory 28 can include computer system readable media in the form of volatile memory, such as random access memory (RAM) 30 and/or cache memory 32. Computer system/server 12 may further include other removable/non-removable, volatile/non-volatile computer system storage media. By way of example only, storage system 34 can be provided for reading from and writing to a non-removable, non-volatile magnetic media (not shown and typically called a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 18 by one or more data media interfaces. As will be further depicted and described below, memory 28 may include at least one program product having a set (e.g., at least one) of program modules that are configured to carry out the functions of embodiments of the disclosure.

Program/utility 40, having a set (at least one) of program modules 42, may be stored in memory 28 by way of example, and not limitation, as well as an operating system, one or more application programs, other program modules, and program data. Each of the operating system, one or more application programs, other program modules, and program data or some combination thereof, may include an implementation of a networking environment. Program modules 42 generally carry out the functions and/or methodologies of embodiments as described herein.

Computer system/server 12 may also communicate with one or more external devices 14 such as a keyboard, a pointing device, a display 24, etc.; one or more devices that enable a user to interact with computer system/server 12; and/or any devices (e.g., network card, modem, etc.) that enable computer system/server 12 to communicate with one or more other computing devices. Such communication can occur via Input/Output (I/O) interfaces 22. Still yet, computer system/server 12 can communicate with one or more networks such as a local area network (LAN), a general wide area network (WAN), and/or a public network (e.g., the Internet) via network adapter 20. As depicted, network adapter 20 communicates with the other components of computer system/server 12 via bus 18. It should be understood that although not shown, other hardware and/or software components could be used in conjunction with computer system/server 12. Examples, include, but are not limited to: microcode, device drivers, redundant processing units, external disk drive arrays, RAID systems, tape drives, and data archival storage systems, etc.

The present disclosure may be embodied as a system, a method, and/or a computer program product. The computer program product may include a computer readable storage medium (or media) having computer readable program instructions thereon for causing a processor to carry out aspects of the present disclosure.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A method comprising:
reading a proposed boundary of a geographic area;
reading one or more boundary validation criteria, each validation criteria representing information usable to indicate whether proposed boundaries are actual boundaries for geographic areas;
applying a machine learning model to satellite imagery of the geographic area, the machine learned model:
forecasting, based on the satellite imagery, a plurality of vegetative indices for the geographic area for a time period;
determining, based on the plurality of vegetative indices, a crop type of the geographic area for the time period; and
identifying the vegetative indices and the crop type as one or more attributes of the geographic area;
determining, from satellite imagery of the geographic area, one or more attribute of the geographic area over time;
validating the proposed boundary by comparing the one or more boundary validation criteria to the one or more attributes of the geographic area; and
responsive to the validation indicating the proposed boundary is not an actual boundary of the geographic area, generating a revised boundary representing the actual boundary of the geographic area based on the proposed boundary and the one or more attributes.

2. The method of claim 1, wherein the geographic area is an agricultural field.

3. The method of claim 1, wherein the one or more boundary validation criteria is based on a program eligibility.

4. (canceled)

5. The method of claim 1, wherein generating the revised boundary comprises removing from the proposed boundaries not conforming to the one or more boundary validation criteria.

6. The method of claim 1, further comprising receiving the proposed boundary from a user via drawing on a map presented within a GUI of a user device.

7. The method of claim 1, further comprising receiving from a user a list of field boundaries, wherein the proposed boundary is selected from the list.

8. The method of claim 1, further comprising:
presenting the proposed boundary and the revised boundary to a user on a map presented within a GUI of a user device.

9. The method of claim 8, further comprising:
receiving from the user an indication of acceptance or rejection of the revised boundary.

10. The method of claim 1, wherein the satellite imagery is provided to the machine learning model over time.

11. The method of claim 10, wherein the machine learning model is configured to provide an in-season estimate of one or more crop type.

12. The method of claim 10, wherein the machine learning model comprises:
a plurality of forecast models, each forecast model configured to forecast a vegetative index; and
a classification model configured to receive the forecasted vegetative indices and determine therefrom the crop type.

13. The method of claim 12, wherein each of the plurality of forecast models comprises an artificial neural network.

14. The method of claim 13, wherein the artificial neural networks comprise a convolutional or recurrent neural network.

15. The method of claim 12, wherein the classification model comprises a gradient boosting model.

16. (canceled)

17. A system comprising:
one or more processors;
a computing node comprising a computer readable storage medium storing computer program instructions, the computer program instructions, when executed by the one or more processors, causing the one or more processors to:
reading a proposed boundary of a geographic area;
read one or more boundary validation criteria, each validation criteria representing information usable to indicate whether proposed boundaries are actual boundaries for geographic areas;
apply machine learned model to satellite imagery of the geographic area, the machine learned model:
forecasting, based on the satellite imagery, a plurality of vegetative indices for the geographic area for a time period;
determining, based on the plurality of vegetative indices, a crop type of the geographic area for the time period; and
identifying the vegetative indices and the crop type as one or more attributes of the geographic area;
determine, from satellite imagery of the geographic area, one or more attribute of the geographic area over time;
validate the proposed boundary by comparing the one or more boundary validation criteria to the one or more attributes of the geographic area; and
responsive to the validation indicating the proposed boundary is not an actual boundary of the geographic area, generate a revised boundary representing the actual boundary of the geographic area based on the proposed boundary and the one or more attributes.

18. (canceled)

19. A non-transitory computer-readable storage medium comprising computer program instructions that, when executed by one or more processors, cause the one or more processors to:
read a proposed boundary of a geographic area;
read one or more boundary validation criteria, each validation criteria representing information usable to indicate whether proposed boundaries are actual boundaries for geographic areas;
apply machine learned model to satellite imagery of the geographic area, the machine learned model:
forecasting, based on the satellite imagery, a plurality of vegetative indices for the geographic area for a time period;
determining, based on the plurality of vegetative indices, a crop type of the geographic area for the time period; and
identifying the vegetative indices and the crop type as one or more attributes of the geographic area;
determine, from satellite imagery of the geographic area, one or more attribute of the geographic area over time;
validate the proposed boundary by comparing the one or more boundary validation criteria to the one or more attributes of the geographic area; and
responsive to the validation indicating the proposed boundary is not an actual boundary of the geographic area, generate a revised boundary representing the actual boundary of the geographic area based on the proposed boundary and the one or more attributes.
